(19) United States
(12) Patent Application Publication
(10) Pub. No.: US 2020/0357678 A1
(43) Pub. Date: Nov. 12, 2020

(54) EJECTOR DEVICE

(71) Applicant: Chun-Wei TSAI, Taoyuan City (TW)

(72) Inventor: Chun-Wei TSAI, Taoyuan City (TW)

(21) Appl. No.: 16/854,900

(22) Filed: Apr. 22, 2020

(30) Foreign Application Priority Data
May 8, 2019 (TW) 108115797

(51) Int. Cl. H01L 21/683

(52) U.S. Cl. CPC H01L 21/6835; H01L 2221/68318; H01L 2221/68386; H01L 21/6838

(57) ABSTRACT

The invention discloses an ejector device for ejecting a chip disposed on a thin film. The chip has a first length in a first direction and a first width in a second direction. The ejector device comprises a pin cover defining a contacting surface. A pin hole, disposed on the contacting surface, has a second length in the first direction and a second width in the second direction. The contacting surface is configured to come into contact with the thin film. When the first length is larger than the second length, the first width is not larger than the second width. When the first width is larger than the second width, the first length is not larger than the second length.

### BACKGROUND OF THE INVENTION

### Cross Reference to Related Application

The present application claims priority to Taiwan patent application Serial No. 108115797 filed on May 8, 2019, the entire content of which is incorporated by reference to this application.

### 1. Field of the Invention

The present invention pertains to an ejector device, more specifically to an ejector device for ejecting a chip from a thin film.

### 2. Description of the Prior Art

Conventionally, after all the semiconductor fabrications for a wafer is completed, the wafer will undergo processes of alignment and dicing, such that the wafer will be cut into many chips having their specific functions. Those diced chips will usually be adhered to a thin film and uniformly arranged. In generally, the advantage of using the thin film to attach the chips is that it can avoid the friction or collision among the chips, thereby reducing damages to occur during the delivery process. Also, as the adhesive material is temporarily used to attach and fix the chips, the process to pick up the chips is also relatively easy and it does not require precise equipments, thus improving the efficiency to pick up the chips from the wafer.

For example, conventionally when it comes to picking up a chip, it often requires using a pin under the thin film to push the chip out; after the chip is lifted or removed from the thin film, then the chip may be picked up by sucking or a tweezer. However, as the adhesive property of the thin film may be different in different regions, it is usually unable to fully lift or peel the chip from the thin film by using the pin to push the chip; there is also a large possibility to unsuccessfully pick up the chip by sucking or the tweezer. Also, if the chip has a rectangle shape or the structure is relatively fragile, then it is even likely to directly break or damage the chip in the process of pushing the chip by the pin. Accordingly, there is a need for a new ejector device in industry to make the chip easily peeled from the thin film while the pin is pushing the chip on the thin film, thereby reducing the possibility of breaking or damaging the chip.

### SUMMARY OF THE INVENTION

The present invention provides an ejector device, having a more advanced design of a pin cover, to more easily peel a chip from a thin film, thereby reducing the possibility of breaking or damaging the chip.

The present invention discloses an ejector device for ejecting a chip. The chip is disposed on a thin film and has a first length in a first direction and a first width in a second direction. The ejector device comprises a pin cover, defining a contacting surface. A pin hole is disposed on the contacting surface and has a second length in the first direction and a second width in the second direction. The contacting surface is configured to come into contact with the thin film. When the first length is larger than the second length, the first width is not larger than the second width. Alternatively, when the first width is larger than the second width, the first length is not larger than the second length.

In one embodiment, the pin cover further comprises a plurality of extraction holes on the contacting surface. Said extraction holes are connected to a pumping system. When the contacting surface comes into contact with the thin film, the pumping system provides a negative pressure through the extraction holes to suck the thin film. Herein, the pin cover may comprise a first recessed region, disposed on the contacting surface, wherein the first recessed region extends along the first direction, and at least a portion of the extraction holes are disposed in the first recessed region. The pin cover may also comprise a second recessed region, disposed on the contacting surface, wherein the second recessed region extends along the second direction, and at least a portion of the extraction holes are disposed in the second recessed region. The pin cover may further comprise a third recessed region, disposed on the contacting surface, wherein the third recessed region surrounds the pin hole, and at least a portion of the extraction holes are disposed in the third recessed region. Additionally, the pin cover may further comprise a plurality of fourth recessed regions, disposed on the contacting surface, wherein each of the extraction holes corresponds to one of the fourth recessed regions, and each area of the fourth recessed regions on the contacting surface is larger than the area of one of the extraction holes on the contacting surface.

In one embodiment, the ejector device may comprise a first pin. The first pin may selectively protrude from the contacting surface through the pin hole. A top surface of the first pin has a third length in the first direction, and the top surface has a third width in the second direction, wherein the third length is larger than the third width. Also, the ejector device may comprise a second pin and a third pin. The second pin and the third pin may selectively protrude from the contacting surface through the pin hole. The second pin is separated from the third pin by a first distance, and the ratio of the first distance to the second length is between 0.3 and 0.7

In on embodiment, the pin hole may be a rectangle, wherein the second length is the length of a longer side of the rectangle, and the second width is the length of a shorter side of the rectangle. Alternatively, the pin hole may also be an ellipse, wherein the second length is the length of a major axis of the ellipse, and the second width is the length of a minor axis of the ellipse.

Based on the above, the ejector device provided in the present invention has a new design of the pin cover. The pin hole on the pin cover may allow the pin to pass through freely, and the length of one side of the pin hole is smaller than the length of the corresponding side of the chip as well. Accordingly, when the thin film is slightly depressed in the pin hole, it will allow the chip to block the contacting surface and make the chip more easily peeled from the thin film, thereby avoiding the possibility of breaking or damaging the chip.

### BRIEF DESCRIPTION OF THE APPENDED DRAWINGS

FIG. 1 is a pictorial view of an ejector device in accordance with an embodiment of the present invention.

FIG. 2 is a pictorial view showing a portion of an ejector device in accordance with an embodiment of the present invention.

FIG. 3 is a view showing an operation of an ejector device in accordance with an embodiment of the present invention.

FIG. 4 is a pictorial view of an ejector device in accordance with another embodiment of the present invention.

FIG. 5 is a pictorial view showing a portion of an ejector device in accordance with another embodiment of the present invention.

### DETAILED DESCRIPTION OF THE INVENTION

The features, objections, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

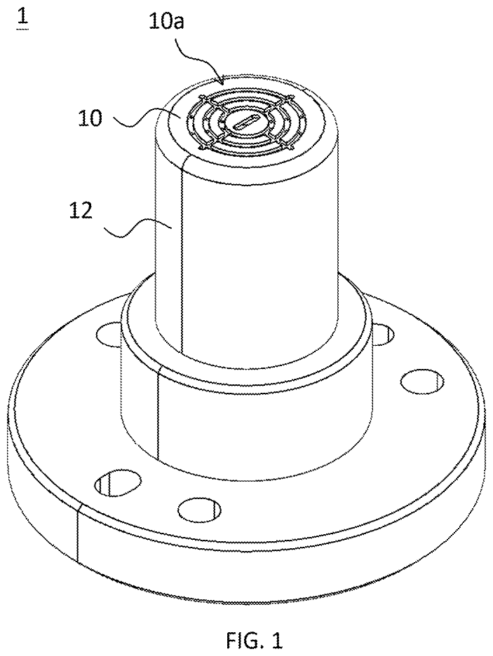

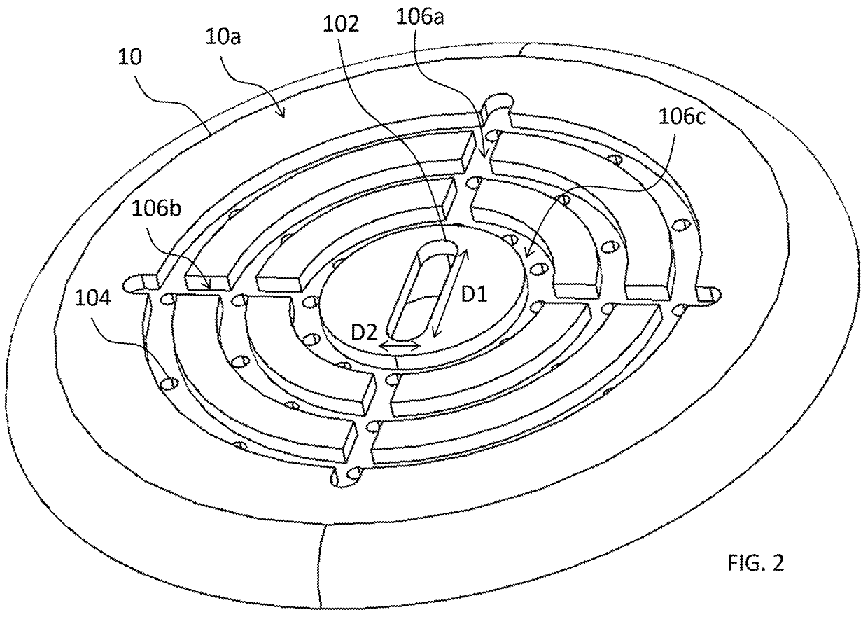

FIG. 1 is a pictorial view of an ejector device in accordance with an embodiment of the present invention. FIG. 2 is a pictorial view showing a portion of an ejector device in accordance with an embodiment of the present invention. Please refer to FIG. 1 and FIG. 2, the ejector device 1 may comprise a pin cover 10 and a base 12. The pin cover 10 is configured to one end of the base 12, and the pin cover 10 defines a contacting surface 10a facing the outer side of the ejector device 1. In one embodiment, the structure of the pin cover 10 and the base 12 may be integrally formed. Alternatively, the structure of the pin cover 10 may be plate-shaped or sheet-shaped, and the pin cover 10 may be separable for assembling to one end of the base 12, which is not limited in the present embodiment. If the pin cover 10 and the base 12 are separable, then the ways to assemble the pin cover 10 and the base 12 are also not limited in the present embodiment. For example, the pin cover 10 and the base 12 may be latched, adhered, or screwed together, etc. As long as the pin cover 10 and the base 12 may be firmly put together, then it will fall within the scope of said pin cover 10 and said base 12 in the present embodiment. Besides, the base 12 may be a kind of a hallow pipe or a hallow column. The base 12 may have a certain hardness, and there may be an accommodating space inside the base 12 (not shown). Practically, said accommodating space may be configured to accommodate a pin (not shown) or a portion of a pumping system (not shown). For example, extraction pipes for connecting the pumping system may be accommodated in said accommodating space. Besides, the base 12 may be used to protect the pin or the pumping system, and thus avoid the pin or the pumping system suffering from external extruding or bending from the side of the base 12.

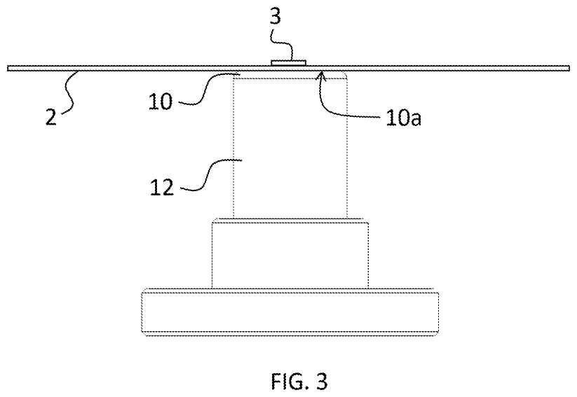

Take the pin cover 10 illustrated in FIG. 1 and FIG. 2 as an example, the top surface on the outer side of the pin cover 10 may define a contacting surface 10a, and the contacting surface 10a may be regarded as the most protruding end of the ejector device 1. Practically, to eject a chip on a thin film by the ejector device 1, the contacting surface 10a may directly come into contact with thin film. To demonstrate how the ejector device 1 operates, please refer to FIG. 2 and FIG. 3, wherein FIG. 3 illustrates a view showing an operation of an ejector device in accordance with an embodiment of the present invention. As shown in FIG. 2 and FIG. 3, a chip 3 may be adhered to one side of a thin film 2. The contacting surface 10a on the pin cover 10 may come into contact with the other side of the thin film 2, and the pin cover 10 and the chip 3 are just in the opposite positions of the two sides of the thin film 2. In other words, the contacting surface 10a on the pin cover 10 may directly come into contact with the thin film 2, and indirectly come into contact with the chip 3 through the thin film 2. In one example, to make the ejector device 1 accurately eject the chip 3, a position calibration for the ejector device 1 and the chip 3 may be performed prior to ejection. Herein, whether it is to fix the ejector device 1 and move the thin film 2, or to fix the thin film 2 and move the ejector device 1, is not limited in the present embodiment. As long as the ejector device 1 and the chip 3 may be calibrated for each other, it is within the scope of the present embodiment.

In a practical example, when observing from one upper side of the chip 3, the shape of the chip 3 may usually appear rectangular. That is, the chip 3 may have a first length in a first direction and a first width in a second direction. To facilitate illustration, the first direction and the second direction may be the directions of the two perpendicular sides of a rectangle, i.e. the first direction is perpendicular to the second direction. In other words, the first length may be the length of one side of the chip 3 in the first direction, and the first width may be the length of the other side of the chip 3 in the second direction. If the chip 3 is a square, then the first length may be equal to the first width. If the chip is a rectangle, then the first length (i.e. the length of the longer side) may be larger than the first width (i.e. the length of the shorter side).

Please continue to refer to FIG. 2, the contacting surface 10a of the pin cover 10 may comprise a pin hole 102, and the pin hole 102 may be generally in the center region of the contacting surface 10a, which is not limited in the present embodiment. Under the situation that the position calibration is already performed for the ejector device 1 and the chip 3, a portion of the vertically projected area of the chip 3 may overlap with the vertically projected area of the pin hole 102. That is, under the situation that the position calibration is already performed for the ejector device 1 and the chip 3, the position of the chip 3 may not only correspond to the pin hole 102, but the shape of the chip 3 may also basically correspond to the opening shape of the pin hole 102 (e.g. same as the longer and shorter sides of the rectangle in their extended directions). In one example, the pin hole 102 comprises an opening length D1 (i.e. a second length) in the first direction, and an opening width D2 in the second direction (i.e. a second width).

In one example, the opening length D1 of the pin hole 102 may be larger than the opening width D2, such that the pin hole 102 may be a rectangle. Alternatively, the opening length D1 of the pin hole 102 may generally be equal to the opening width D2, such that the pin hole 102 may be a square. However, the pin hole 102 may not necessarily have an angle at the corner in the rectangle (or square). As illustrated in FIG. 2, the corner angle of the pin hole 102 may be arc-shaped, such that the shape of the pin hole 102 may be closer to the shape of a capsule. Additionally, the shape of the pin hole 102 may be closer to an ellipse, being non-rectangular. Suppose the shape of the pin hole 102 is an ellipse, then the opening length in the first direction (i.e. the second length) may be the major axis of the ellipse, and the opening width in the second direction (i.e. the second width) may be the minor axis of the ellipse.

It is worth mentioning that, although the thin film 2 may be of soft materials, with an appropriate design of the opening shape of the pin 102, basically the chip 3 will not be sucked in the pin hole 102. That is, when engineers already know that the ejector device 1 is used for which size and specification of the chip 3, by designing the pin hole 102 on the pin cover 10, the chip 3 can avoid being sucked in the pin hole 102. To avoid the chip 3 being sucked in the pin hole 102, the present embodiment provides many possible ways to design the pin hole 102. In one of the examples, the lengths of the chip 3 in the first direction and the second direction are already known, thus when the length of the chip 3 in the first direction (i.e. the first length) is larger than the opening length D1 of the pin hole 102 in the first direction (i.e. the second length), the length of the chip 3 in the second direction (i.e. the first width) is not larger than the opening width D2 of the pin hole 102 in the second direction (i.e. the second width). For another example, when the length of the chip 3 in the second direction (i.e. the first width) is larger than the opening width D2 of the pin hole 102 in the second direction (i.e. the second width), the length of the chip 3 in the first direction (i.e. the first length) is not larger than the opening length D1 of the pin hole 102 in the first direction (i.e. the second length).

That the chip 3 will not be sucked in the pin hole 102 illustrated in the present embodiment is meaningful in practice. In a practical operating example, when the position calibration of the ejector device 1 and the chip 3 is completed and when the ejector device 1 is about to eject the chip 3, the contacting surface 10a will come into contact with the thin film 2, and the pumping system will be activated. In one example, there are a plurality of extraction holes 104 on the contacting surface 10a of the pin cover 10. Said plurality of extraction holes 104 may be connected to said pumping system through extraction pipes, and the extraction pipes may be accommodated in the base 12. When the pumping system is activated, the pumping system provides a negative pressure through the extraction pipes to make the extraction holes 104 in the state of extracting gas (i.e. to start sucking gas into the extraction holes 104). At this moment, as the extraction holes 104 are connected to the extraction pipes having negative pressure, the thin film 2 will be closely sucked and adhered to the contacting surface 10a. Particularly, the thin film 2 on the pin hole 102 will tend to be depressed in the pin hole 102 due to the pulling force of the suction resulting from the negative pressure. However, the thin film 2 above is sticking to the chip 3 and the chip 3 will not be depressed in the pin hole 102, such that the thin film 2 that is sticking to the chip 3 will not be easily depressed in the pin hole 102.

Notably, the present embodiment does not aim to make the thin film 2 and the chip 3 which is sticking to the thin film 2 to be depressed together in the pin hole 102. Instead, the present embodiment utilizes the design of the pin hole 102 being relatively smaller than the chip 3, to let the chip 3 block the top of the pin hole 102 (i.e. to block the contacting surface 10a), thereby making the thin film 2 to be pulled toward the pin hole 102. A person having ordinary skill in the art may understand that, by adjusting the values of the negative pressure provided in the pumping system, as long as the pulling force from the negative pressure is slightly larger than the adhesive force between the thin film 2 and the chip 3, then it can properly separate the thin film 2 from the chip 3. In one example, the pulling force from the negative pressure may be 101% to 105% of the adhesive force between the thin film 2 and the chip 3. Such percentage is related to the time for separating the thin film 2 and the chip 3; when the difference between the pulling force and the adhesive force is larger, it is much faster to separate the thin film 2 and the chip 3. A person having ordinary skill in the art may adjust the pulling force and the adhesive force according to the need.

It is worth mentioning that, the chip 3 will be easily picked up after the chip 3 is peeled from the thin film 2 by a certain area. To make the chip 3 more easily peeled from the thin film 2 by a certain area and to facilitate the operation in practice, one of the opening length D1 or the opening width D2 of the pin hole 102 in the present embodiment may be smaller than the length corresponding to the chip 3, whereas the other opening length D1 or the opening width D2 may be larger than the other length corresponding to the chip 3. Thus, the area of the pin hole 102 may be larger and the region to provide the negative pressure may also be larger. Also, as the pin hole 102 has one side being longer than the chip 3, the thin film 2 which is revealed from the chip 3 but within the range of the pin hole 102, may not be subjected to the adhesive force of the chip 3, and may quickly be depressed in the pin hole 102. Subsequently, the thin film 2 that is already depressed in the pin hole 102 may laterally pull the thin film 2 under the chip 3, making the thin film 2 under the chip 3 more easily depressed in the pin hole 102 and separated from the chip 3. In other words, the design of the pin hole 102 in the present embodiment may allow the chip 3 to quickly separate from the thin film 2 through the lateral side; meanwhile, it may also allow the chip 3 to be stucked on the side of the pin hole 102 that is shorter than the chip 3, thereby increasing the efficiency to separate the chip 3 from the thin film 2 and its convenience.

Conversely, if the opening length or the opening width are both larger than the lengths corresponding to the chip 3, then it indicates that the area of the chip 3 is smaller than the area of the pin hole 102. Herein, the chip 3 and the thin film 2 will be sucked in the pin hole 102 together, making it not easy to separate the thin film 2 from the chip 3 by the pulling force from the negative pressure. On the other hand, if the opening length or the opening width of the pin hole 102 are both smaller or equal to the lengths corresponding to the chip 3, then it indicates that the area of the chip 3 is larger than or equal to the area of the pin hole 102. Herein, different from the design in the present embodiment, the chip 3 may be quickly peeled from the thin film 2 through the lateral side; if the pin hole 102 is too small, then the thin film 2 may only be pulled by the pulling force from the negative pressure below. Apparently, with such undersize design of the pin hole, it may require much larger negative pressure to separate thin film 2 and the chip 3 by a certain area, which will also increase the time for separating the thin film 2 and the chip 3.

On the other hand, to make the thin film 2 more closely adhered to the contacting surface 10a, the plurality of the extraction holes 104 on the contacting surface 10 may be uniformly disposed, making the thin film 2 subject to the pulling force from the negative pressure with a larger area. The arrangement and the pattern of the plurality of the extraction holes 104 are not limited in the present embodiment. For example, the plurality of the extraction holes 104 may be disposed according to an array pattern, or the plurality of the extraction holes 104 may have a pattern spreading from the center as shown in FIG. 2. In addition, the contacting surface 10a may further comprise one or more types of recessed regions. As shown in FIG. 2, the contacting surface 10a may have a recessed region 106a (i.e. a first recessed region) and the recessed region 106a extends along the first direction, and at least a portion of the extraction holes 104 are disposed in the recessed region 106a. Herein, the axis of the recessed region 106a may be the same as the longer axis of the pin hole 102 (i.e. the first direction). In other words, a portion of the extraction holes 104 may be disposed on the longer axis of the pin hole 102. Accordingly, the thin film 2, which is already depressed in the recessed region 106a in the direction of the longer axis of the pin hole 102, is also possible to laterally pull the thin film 2 under the chip 3, making the thin film 2 under the chip 3 more easily separated from the chip 3. The length and the width of the recessed region 106a are not limited in the present embodiment; as long as the extraction holes 104 may be disposed in the recessed region 106a, it would fall within the scope of said first recessed region in the present embodiment.

Additionally, the contacting surface 10a may also have a recessed region 106b (i.e. a second recessed region). The recessed region 106b may extend to the second direction and at least a portion of the extraction holes 104 are disposed in the recessed region 106b. Herein, the axis of the recessed region 106b may be the same as the shorter axis of the pin hole 102 (i.e. the second direction). In other words, a portion of the extraction holes 104 may be disposed on the shorter axis of the pin hole 102. Accordingly, the thin film 2, which is already depressed in the recessed region 106b in the direction of the shorter axis of the pin hole 102, is also possible to laterally pull the thin film 2 under the chip 3, making the thin film 2 under the chip 3 more easily separated from the chip 3. The length and the width of the recessed region 106b are not limited in the present embodiment; as long as the extraction holes 104 may be disposed in the recessed region 106b, it would fall within the scope of said second recessed region in the present embodiment.

Moreover, the contacting surface 10a may also have a recessed region 106c (i.e. a third recessed region). The recessed region 106c may surround the pin hole 102, and at least a portion of the extraction holes 104 are disposed in the recessed region 106c. Herein, although three concentric ring-shaped recessed regions 106c are shown in FIG. 2, the number of the recessed region 106c is not limited in the present embodiment. For example, there may be just one recessed region 106c. Accordingly, the thin film 2, which is depressed in the recessed region 106c and surrounds the pin hole 2, may also laterally pull the thin film 2 under the chip 3, allowing the thin film 2 under the chip 3 more easily separated from the chip 3. The size and the width of the recessed region 106c are not limited in the present embodiment; as long as the extraction holes 104 may be disposed in the recessed region 106c and the ring center position of the recessed region 106c is generally the same as the center position of the pin hole 102, it would fall within the scope of said third recessed region in the present embodiment.

In a practical operating example, when the thin film 2 under the chip 3 is just slightly separated from the chip 3, or the thin film 2 is separated from the chip 3 by a certain area, then the present embodiment may then drive the pin, making the pin protrude from the contacting surface 10a through the pin hole 102. Such pin may have a top surface for pushing the thin film 2 and further pushing the chip 3 which is situated on the thin film 2. In one example, the shape of the pin may be close to the shape of the pin hole 102; that is, said top surface may also have a third length in the first direction and a third width in the second direction. When the shape of the pin hole 102 is close to a rectangle or an ellipse, then the third length is larger than the third width. Herein, since the top surface of the pin may not be pin-like but rather have a certain area, and since the thin film 2 is already slightly separated form the chip 3, when the pin pushes the thin film 2, the force applied on the chip 3 situated on the thin film 2 will be more equally distributed; also, as the adhesive force between the thin film 2 and the chip 3 is relatively low, it can avoid breaking or damaging the chip 3. For example, the top surface area of the pin may be 5%˜35% of the area of the pin hole 102; such percentage may also be 10%, 20% or 30%, which is not limited in the present embodiment. Said area of the pin hole 102 is supposed to correspond the whole depressed area of where the chip 3 is located and does not include the depressed area which basically does not correspond to the location of the chip 3 (i.e. the recessed regions 106a, 106b or 106c).

In another example, the quantity of the pin may be more than two. The adjacent pins may be separated by a certain distance. If the quantity of the pin is two, then the two pins are arranged along the first direction. Herein, the distance between the two pins (i.e. the first distance) may be proportional to the opening length D1 of the pin hole 102 in the first direction (i.e. the second length). For example, the ratio of the first distance to the opening length D1 may be between 0.3 and 0.7; such ratio may also be 0.4, 0.5, 0.6, etc., which is not limited in the present embodiment. Suppose the quantity of the pin is three, and the three pins are arranged along the first direction. Then, the distance between the first pin and the last pin in the first direction may be a second distance, and the ratio of the second distance to the opening length D1 may be between 0.3 and 0.7 likewise; such ratio may also be 0.4, 0.5, 0.6, etc., which is not limited in the present embodiment.

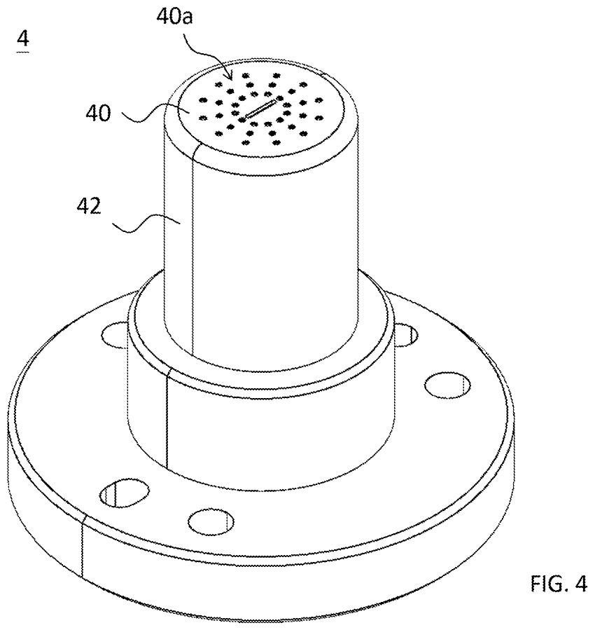

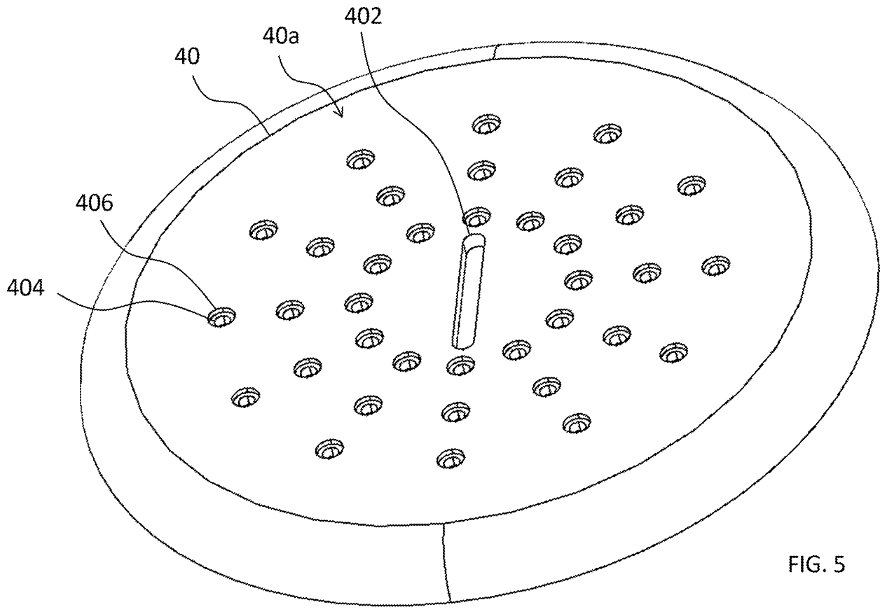

The present embodiment does not only have said types of recessed regions. Please refer to FIG. 4 and FIG. 5, wherein FIG. 4 is a pictorial view of an ejector device in accordance with another embodiment of the present invention, and FIG. 5 is a pictorial view showing a portion of an ejector device in accordance with another embodiment of the present invention. As shown in FIG. 4 and FIG. 5, the ejector device 4 may also have the pin cover 40 and the base 42 in another embodiment of the present invention. Similar to the previous embodiment, the pin cover 40 may also have a contacting surface 40a, pin hole 402, and extraction holes 404. Besides, the base 12 and the base 42 are generally the same. The descriptions of these units are not repeated here. The pin cover 40 is disposed on one end of the base 42 likewise, and the pin cover 40 also defines the contacting surface 40a facing to the outer side of the ejector device 4. In addition, the structure of the pin cover 40 and the base 42 may also be integrally formed, or the structure of the pin cover 40 may be plate-shaped or sheet-shaped. Similarly, the pin cover 40 may be separable to be assembled to one end of the base 42, which is not limited in the present embodiment.

Different from the previous embodiment, the shapes of the recessed regions of the contacting surface 40a are different from those on the contacting surface 10a. As shown in FIG. 5, the contacting surface 40a may have a plurality of recessed regions 406 (i.e. a plurality of fourth recessed regions), and the recessed regions 406 surround the extraction holes 404. In on example, the recessed region 406 corresponds to the extraction hole 404 one-to-one; that is, one recessed region 406 surrounds one extraction hole 404. Besides, according to FIG. 5, the area of the recessed region 406 on the contacting surface 40a is larger than the area of the extraction hole 404 on the contacting surface 40a, allowing the extraction hole 404 to be within the recessed region 406. Accordingly, as the thin film will be depressed in the recessed regions 406 that are uniformly distributed on the contacting surface 40a, the thin film will be more firmly sucked on the pin cover 40. This would maintain the lateral tension of thin film and pull the thin film under the chip, allowing the thin film under the chip to be more easily separated from the chip. The present embodiment does not limit the size and width of the recessed region 406, as long as the extraction hole 404 may be disposed within the recessed region 406, it would fall within the scope of said fourth recessed region in the present embodiment.

In summary, the ejector device provided in the present invention has a new design of the pin cover. The pin hole on the pin cover may allow the pin to pass through freely, and the length of one side of the pin hole is smaller than the length of the corresponding side of the chip as well. Accordingly, when the thin film is slightly depressed in the pin hole, it will allow the chip to block the contacting surface and make the chip more easily peeled from the thin film, thereby avoiding the possibility of breaking or damaging the chip.

What is claimed is:

1. An ejector device for ejecting a chip disposed on a thin film, the chip having a first length in a first direction and a first width in a second direction, the ejector device comprising:
a pin cover defining a contacting surface, wherein a pin hole, disposed on the contacting surface, has a second length in the first direction and a second width in the second direction;
wherein the contacting surface is configured to come into contact with the thin film, when the first length is larger than the second length, the first width is not larger than the second width, and when the first width is larger than the second width, the first length is not larger than the second length; and
wherein the pin cover further comprises a plurality of extraction holes and a third recessed region, disposed on the contacting surface, wherein the third recessed region surrounds the pin hole, and at least a portion of the extraction holes are disposed in the third recessed region.

2. The ejector device according to claim 1, wherein the extraction holes are connected to a pumping system, and when the contacting surface comes into contact with the thin film, the pumping system provides a negative pressure through the extraction holes to suck the thin film.

3. The ejector device according to claim 2, wherein the pin cover further comprises a first recessed region, disposed on the contacting surface, wherein the first recessed region extends along the first direction, and at least a portion of the extraction holes are disposed in the first recessed region.

4. The ejector device according to claim 2, wherein the pin cover further comprises a second recessed region, disposed on the contacting surface, wherein the second recessed region extends along the second direction, and at least a portion of the extraction holes are disposed in the second recessed region.

5. The ejector device according to claim 2, wherein the pin cover further comprises a plurality of fourth recessed regions, disposed on the contacting surface, wherein each of the extraction holes corresponds to one of the fourth recessed regions, and each area of the fourth recessed regions on the contacting surface is larger than the area of one of the extraction holes on the contacting surface.

6. The ejector device according to claim 1, further comprises a first pin, wherein the first pin selectively protrudes from the contacting surface through the pin hole, a top surface of the first pin has a third length in the first direction, the top surface has a third width in the second direction, and the third length is larger than the third width.

7. The ejector device according to claim 1, further comprises a second pin and a third pin, wherein the second pin and the third pin selectively protrude from the contacting surface through the pin hole, the second pin is separated from the third pin by a first distance, and the ratio of the first distance to the second length is between 0.3 and 0.7.

8. The ejector device according to claim 1, wherein the pin hole is a rectangle, and the second length is the length of a longer side of the rectangle, and the second width is the length of a shorter side of the rectangle.

9. The ejector device according to claim 1, wherein the pin hole is an ellipse, and the second length is the length of a major axis of the ellipse, and the second width is the length of a minor axis of the ellipse.

10. The ejector device according to claim 1, wherein the second length is larger than the second width.
